(19) United States
(12) Patent Application Publication
(10) Pub. No.: US 2020/0133353 A1
(43) Pub. Date: Apr. 30, 2020

(54) SCREWLESS MOUNTING ASSEMBLY

(71) Applicant: Shenzhen Fugui Precision Ind. Co., Ltd., Shenzhen (CN)

(72) Inventors: XIU-QUAN HU, Shenzhen (CN); LI-WEN GUO, Shenzhen (CN)

(21) Appl. No.: 16/296,355

(22) Filed: Mar. 8, 2019

(30) Foreign Application Priority Data
Oct. 29, 2018 (CN) 201811270573.0

(51) Int. Cl. G06F 1/18; H05K 7/14

(52) U.S. Cl. CPC G06F 1/185; H05K 7/1489

(57) ABSTRACT

A screwless mounting assembly mounts an expansion card in a server. The screwless mounting assembly includes a tray, a flexible bracket, and a mounting member. The tray defines a positioning hole. The bracket includes a number of pegs for mounting the expansion card to the bracket. The mounting member includes a spring pin for mounting the bracket to the tray. When the bracket mounts the expansion card, the bracket is placed on a predetermined location on the tray, and the mounting member is slid along a first direction until the spring pin is aligned with the positioning hole and is received within the positioning hole to mount the bracket to the tray. The spring pin is pulled out of the positioning hole, and the mounting member is slid along a second direction to remove the bracket from the tray.

### FIELD

The subject matter herein generally relates to mounting assemblies, and more particularly to a screwless mounting assembly for mounting an expansion card in a server.

### BACKGROUND

Generally, servers come equipped with expansion cards. Conventionally the expansion cards are mounted to a bracket by screws, and the bracket is mounted to the server by screws. The present disclosure discloses an expansion card mounted to a bracket without screws.

### BRIEF DESCRIPTION OF THE DRAWINGS

Implementations of the present disclosure will now be described, by way of example only, with reference to the attached figures.

FIG. 1 is an isometric view of an embodiment of a screwless mounting assembly.

FIG. 2 shows the screwless mounting assembly in FIG. 1 from another perspective.

FIG. 3 is an exploded view of the screwless mounting assembly.

FIG. 4 is similar to FIG. 3, but showing the screwless mounting assembly from another perspective.

FIG. 5 is a close-up view of a mounting member of the screwless mounting assembly in FIG. 1.

FIG. 6 is a close-up view of a bracket of the screwless mounting assembly in FIG. 1.

### DETAILED DESCRIPTION

It will be appreciated that for simplicity and clarity of illustration, where appropriate, reference numerals have been repeated among the different figures to indicate corresponding or analogous elements. Additionally, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. The drawings are not necessarily to scale and the proportions of certain parts may be exaggerated to better illustrate details and features. The description is not to be considered as limiting the scope of the embodiments described herein.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “substantially” is defined to be essentially conforming to the particular dimension, shape, or other word that “substantially” modifies, such that the component need not be exact. For example, “substantially cylindrical” means that the object resembles a cylinder, but can have one or more deviations from a true cylinder. The term “comprising” means “including, but not necessarily limited to”; it specifically indicates open-ended inclusion or membership in a so-described combination, group, series and the like.

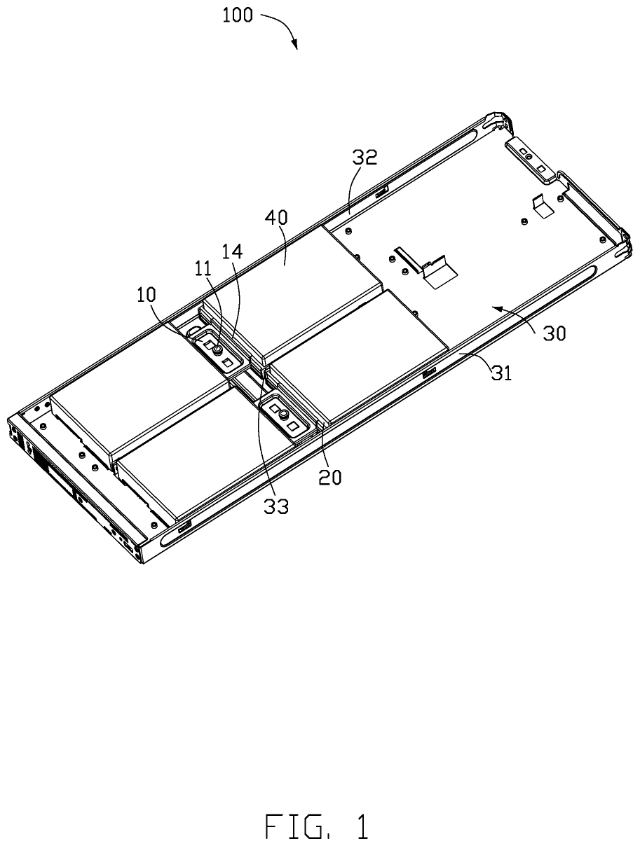

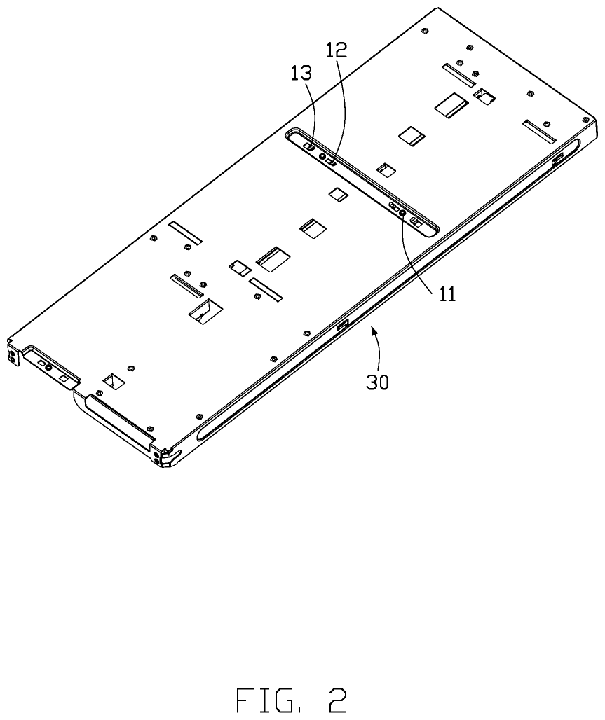

FIGS. 1-4 show an embodiment of a screwless mounting assembly 100 adapted to mount an expansion card 40 in a server (not shown). In one embodiment, the expansion card 40 is a display card. In other embodiments, the expansion card 40 may be other cards. The screwless mounting assembly 100 includes a mounting member 10, a bracket 20, and a tray 30. The mounting member 10 includes a spring pin 11. The bracket 20 is flexible. The bracket 20 includes a plurality of pegs 23 adapted to mount the expansion card 40 to the bracket 20. The mounting member 10 mounts the bracket 20 to the tray 30. The tray 30 defines a positioning hole 36 adapted to receive the spring pin 11. In one embodiment, the tray 30 is mounted in the server.

When the bracket 20 mounted to the expansion card 40 is placed on a predetermined location of the tray 30, the mounting member 10 is slid along a first direction until the spring pin 11 is aligned with the positioning hole 36. When the spring pin 11 is aligned with the positioning hole 36, the spring pin 11 is inserted within the positioning hole 36. Thus, the mounting member 10 mounts the bracket 40 mounted to the expansion card 40 to the tray 30.

To remove the expansion card 40 from the tray 30, the spring pin 11 is pulled out of the positioning hole 36, and the mounting member 10 is slid along a second direction to remove the bracket 20 and the expansion card 40 from the tray 30. In one embodiment, the first direction is opposite to the second direction.

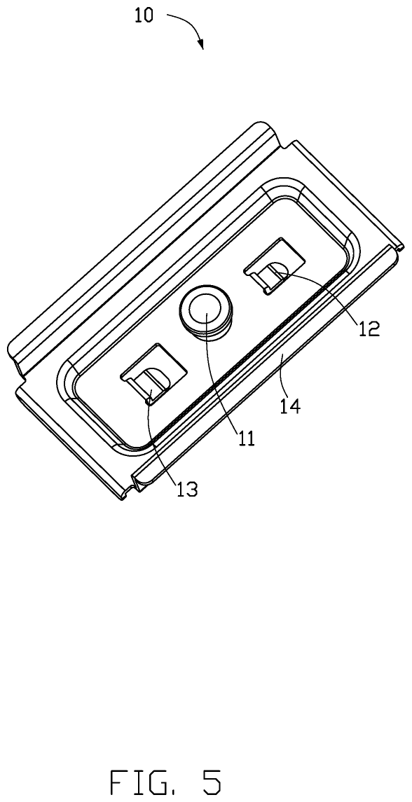

As shown in FIG. 5, the mounting member 10 is substantially rectangular, and the spring pin 11 is located in a central portion of the mounting member 10. The mounting member 10 includes a first buckle 12 and a second buckle 13. The first buckle 12 and the second buckle 13 are respectively located on opposite sides of the spring pin 11. A width of the first buckle 12 is less than a width of the second buckle 13 for foolproof mounting of the mounting member 10 to the bracket 20. Two opposite long sides of the mounting member 10 each include a bent sidewall 14. The bent sidewalls 14 are adapted to latch with the bracket 20. In one embodiment, the spring pin 11 is riveted to the mounting member 10.

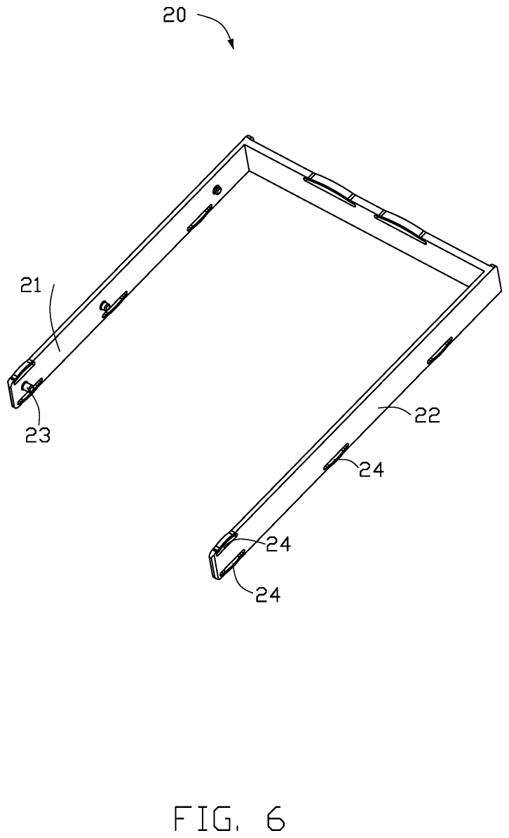

As shown in FIG. 6, the bracket 20 is substantially U-shaped and includes a first arm 21 and a second arm 22. The plurality of pegs 23 extend from an inner side of the first arm 21 and the second arm 22, and the pegs 23 of the first arm 21 and the pegs 23 of the second arm 22 extend toward each other. A length of the plurality of pegs 23 decreases along a direction from a proximal end of the first arm 21 and the second arm 22 to a distal end of the first arm 21 and the second arm 22. Thus, when the pegs 23 located at the distal end of the first arm 21 and the second arm 22 are mounted to the expansion card 40, the next proximal pegs 23 can be mounted to the expansion card 40 with decreasing effort to prevent the first arm 21 and the second arm 22 from being damaged. The bracket 20 defines a plurality of slots 24 for reducing vibration during a process of mounting the mounting member 10 to the tray 30.

To mount the expansion card 40 to the bracket 20, the first arm 21 is flexed to insert the plugs 23 of the second arm 22 into a plurality of mounting holes 41 defined in a side of the expansion card 40. After the plugs 23 of the second arm 22 are inserted into the mounting holes 41, the first arm 21 is released to insert the plugs 23 of the first arm 21 into the mounting holes 41 of another side of the expansion card 40, thereby mounting the expansion card 40 to the bracket 20.

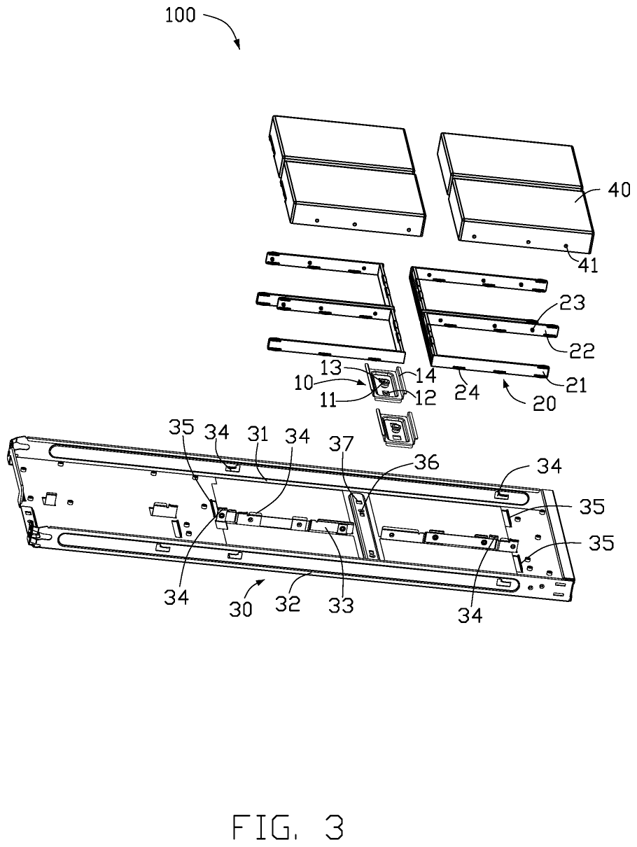

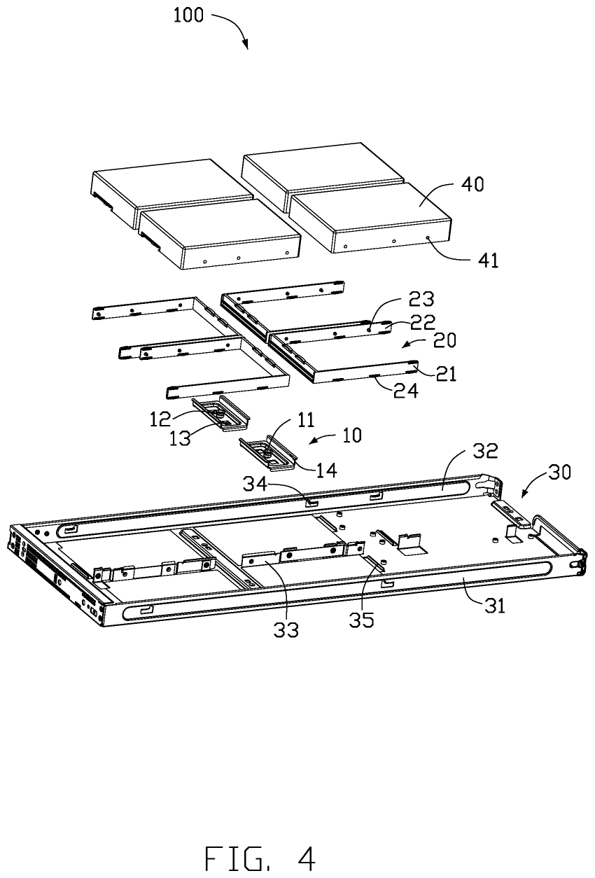

As shown in FIGS. 3 and 4, the tray 30 is substantially rectangular and includes a first sidewall 31, a second sidewall 32, and a middle panel 33. A plurality of abutting portions 34 are formed on the first sidewall 31, the second sidewall 32, and the middle panel 33. The abutting portions 34 are adapted to abut the bracket 20. The tray 30 further includes a limiting portion 35 adapted to prevent the expansion card 40 from moving.

The bracket 20 mounted to the expansion card 40 is mounted to the tray 30. The abutting portions 34 abut the bracket 20, and the limiting portion 35 prevents the expansion card 40 from moving. The mounting member 10 mounts the bracket 20 to the tray 30. The bent sidewalls 14 respectively latch with the two adjacent brackets 20. The spring pin 11 is received within the positioning hole 36 of the tray 30. The first buckle 12 and the second buckle 13 are latched within latching holes 37 of the tray 30 (shown in FIG. 3).

The tray 30 can mount a plurality of brackets 20, such that the mounting member 10 mounts adjacent brackets 20 to the tray 30. In one embodiment, the tray 30 mounts four brackets 20, but is not limited thereto.

The screwless mounting assembly 100 as described above is convenient to use and does not require any external components for mounting the expansion card 40 to the tray 30.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in matters of shape, size and arrangement of the parts within the principles of the present disclosure up to, and including, the full extent established by the broad general meaning of the terms used in the claims.

What is claimed is:

1. A screwless mounting assembly adapted to mount an expansion card in a server, the screwless mounting assembly comprising:
a tray defining a positioning hole;
a flexible bracket comprising a plurality of pegs adapted to mount the expansion card to the bracket;
a mounting member comprising a spring pin, the mounting member adapted to mount the bracket to the tray, and the spring pin adapted to be received in the positioning hole; wherein:
when the bracket is placed on a predetermined location on the tray, and the mounting member is slid along a first direction until the spring pin is aligned with the positioning hole and is received within the positioning hole, the bracket mounts the expansion card to the tray;
when the spring pin is pulled out of the positioning hole, and the mounting member is slid along a second direction, the bracket and the expansion card are removed from the tray.

2. The screwless mounting assembly of claim 1, wherein the mounting member comprises a first buckle and a second buckle adapted to latch with the tray when the mounting member is mounted to the tray.

3. The screwless mounting assembly of claim 2, wherein a width of the first latch is less than a width of the second latch.

4. The screwless mounting assembly of claim 1, wherein the mounting member comprises a bent sidewall adapted to latch with the bracket when the mounting member is mounted to the bracket.

5. The screwless mounting assembly of claim 1, wherein a length of the plurality of pegs decreases along a predetermined direction along the bracket.

6. The screwless mounting assembly of claim 1, wherein the bracket is U-shaped.

7. The screwless mounting assembly of claim 1, wherein the tray comprises an abutting portion adapted to abut the bracket when the bracket is mounted to the tray.

8. The screwless mounting assembly of claim 1, wherein the tray comprises a limiting portion adapted to prevent the expansion card from sliding when the bracket is mounted to the tray.

9. The screwless mounting assembly of claim 1, wherein the tray is adapted to mount a plurality of brackets, and the mounting member mounts two adjacent brackets.
